(19) United States
(12) Patent Application Publication
(10) Pub. No.: US 2002/0053914 A1
(43) Pub. Date: May 9, 2002

(54) Arc location

(75) Inventors: Jonathan Samuel Dring, Cheltenham (GB); Mark Thomas Harrington, Tewkesbury (GB)

Correspondence Address: Burton A. Amernick, Connolly Bove Lodge & Hutz LLP, Suite 800, 1990 M Street, N.W., Washington, DC, 20036-3425, US

(73) Assignee: SMITHS GROUP PLC, London (GB)

(21) Appl. No.: 09/986,184

(22) Filed: Nov. 7, 2001

(30) Foreign Application Priority Data
Nov. 7, 2000 (GB) 0027235.1

(51) Int. Cl. H01H 9/50; G01R 31/08; G01R 31/12

(52) U.S. Cl. 324/536

(57) ABSTRACT

The current and voltage in an electrical system are monitored to detect an occurrence of an arc. The location of the arc is determined by propagating a pulse signal on the system in response to detection of the arc and timing the interval between reception of a portion of the signal reflected back from the location of the arc.

### BACKGROUND OF THE INVENTION

This invention relates to methods and apparatus for determining the location of arcs in electrical systems.

Electrical systems may suffer from arcing between parts of the system at different voltages or between a part of the system and earth. The presence of an arc may be indicative of a breakdown in insulation or some other fault. Because arcing prevents proper operation of the system and may cause damage or fire risk, it is important that the arcing be detected and the location of the arcing be identified rapidly and accurately.

In U.S. Pat. No. 4,316,139 there is described an arc detection system including detectors responsive to vibration and electromagnetic disturbances produced by an arc. The time taken for the vibration and electromagnetic disturbances produced by an arc to reach the detectors is different, thereby enabling the distance of the arcing from the detectors to be determined. U.S. Pat. No. 5,729,144 and WO9742514 describe systems that measure the difference in times of arrival of conducted transient signals on the power line and radiated signals produced by an arc. Such systems may be difficult to use where there is considerable radiated or vibration noise.

### BRIEF SUMMARY OF THE INVENTION

It is an object of the present invention to provide an alternative method and system for locating arcing.

According to one aspect of the present invention there is provided a method of determining the location of arcing in an electrical system including the steps of detecting the occurrence of an arc, propagating a signal on the system in response thereto, detecting a portion of the signal reflected back from the location of the arcing and determining the location from the time between propagation of the signal and reception of the reflected portion of the signal.

The occurrence of an arc may be detected by monitoring the current and voltage in the system, such as by detecting a drop in voltage and an increase in current. The time between propagation and reception may be determined using correlation techniques.

According to a second aspect of the present invention there is provided apparatus for use in a method according to the above one aspect of the present invention.

According to a third aspect of the present invention there is provided apparatus for determining the location of arcing in an electrical system including arc detector means for detecting the occurrence of an arc, generator means for generating a signal on the system in response to an output from the detector means, signal detector means for detecting a portion of the signal reflected from the location of the arcing, and processor means for determining the location of the arcing from the time between generation of the signal on the system and detection of the reflected portion.

The arc detector means may be arranged to monitor current and voltage in the system and may be arranged to respond to a drop in voltage and an increase in current in the system.

According to a fourth aspect of the present invention there is provided an electrical system including apparatus according to the second or third aspect of the present invention.

A system and method according to the present invention, will now be described, by way of example, with reference to the accompanying drawings.

### BRIEF DESCRIPTION OF THE DRAWINGS

FIG. 1 is a schematic diagram of the system; and

FIG. 2 illustrates signals at different locations on the system at different times.

### DETAILED DESCRIPTION OF THE PREFERRED EMBODIMENTS

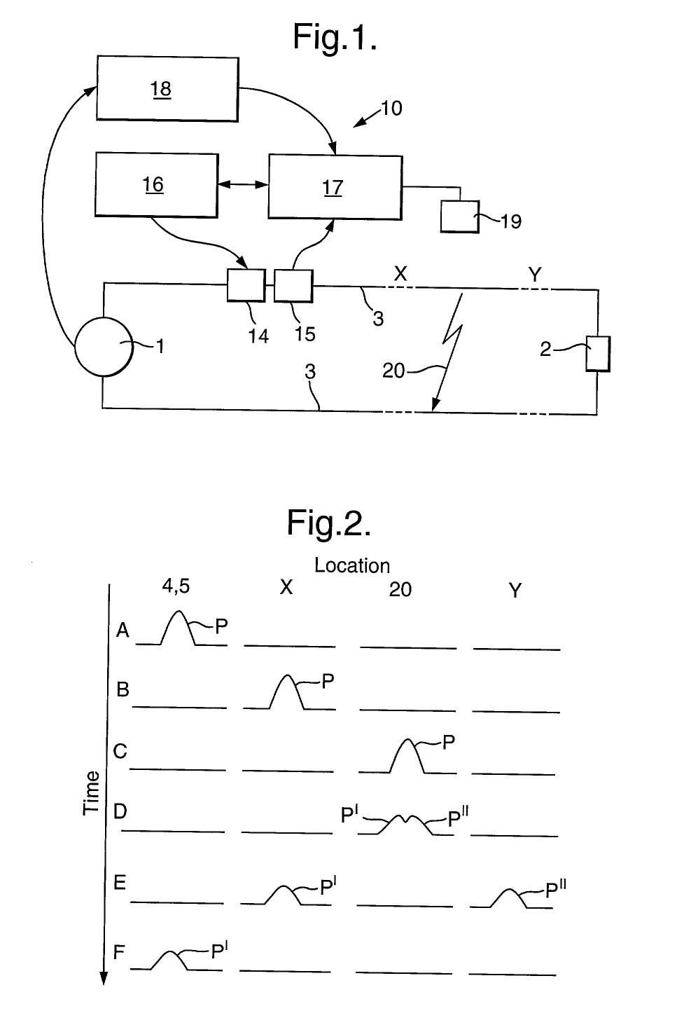

With reference first to FIG. 1, the system includes a power generator 1 connected to a load 2 via a transmission line 3, and arc detection and location apparatus indicated generally by the numeral 10.

The apparatus 10 includes an input coupler 14 and an output coupler 15 connected in the transmission line 3 adjacent one another, the input coupler serving to transmit signals onto the transmission line and the output coupler serving to detect and extract signals from the line. The functions of these two couplers 14 and 15 could be provided by a single device. The input coupler 14 is connected to a signal generator 16. The output coupler 15 is connected to a signal processing unit 17, which also receives an input from the signal generator 16. The apparatus 10 further includes an arc detection unit 18, which may take various different forms. In the present example, the arc detection unit 18 is connected with the power generator 1 to monitor its current and voltage output. When an arc occurs, this causes a characteristic drop in voltage and an increase in current, which is readily detected by the unit 18. Alternatively, an arc detection unit could detect the occurrence of an arc in other ways, such as by detecting the electromagnetic radiation produced by the arc. The output of the arc detection unit 18 is connected to the signal generator 16 via the processing unit 17.

In normal operation, the power generator 1 supplies power to the load 2 via the transmission line 3.

The apparatus 10 determines the location of an arc in the system by time domain reflectometry (TDR) techniques. If an arc 20 should occur between two parts of the transmission line 3, such as from a location between points X and Y on one part of the line to a location at a lower voltage on another part of the line, this will be immediately detected by the arc detection unit 18. In response to this, the arc detection unit 18 provides an output to the signal generator 16 via the processing unit 17 to cause the signal generator to produce a signal, which is propagated onto the transmission line 3 by the coupler 14. This is represented in FIG. 2 by a single pulse P at time A, although the signal could be a pulse train or multiple pulses. This pulse signal P propagates along the line 3 until at time B it has reached point X on the line. At a slightly later time C the pulse P reaches the location of the arc 20. Because the arc 20 causes an impedance discontinuity in the transmission line 3, this will reflect back a portion P′ of the signal pulse P and will pass a portion P″ of the pulse on to the load 2 as shown at time D. At a slightly later time E, the reflected portion P′ of the pulse reaches point X and the other portion P″ reaches the point Y on opposite sides of the location of the arc 20. At time F, the reflected part P′ of the pulse reaches the couplers 14 and 15 where it is detected and passed to the signal processor 17. The signal processor 17 measures the difference in time between transmission of the pulse P and reception of its reflection P′ and from this calculates the distance of the path travelled by the pulse P and its reflected portion P′ from the signal generator 16 to the processor 17 via the arc 20. The processor 17 supplies this information to utilization means 19, such as a display or memory. Preferably correlation techniques are used to extract the timing information from the returned signals because these will also include external noise.

The present invention readily enables the location of arcing to be determined.

What we claim is:

1. A method of determining the location of arcing in an electrical system comprising the steps of: detecting the occurrence of an arc; propagating a signal on the system in response to the detection of an arc; detecting a portion of said signal reflected back from the location of the arcing; and determining said location from the time between propagation of said signal and reception of said reflected portion of said signal.

2. A method according to claim 1, wherein the occurrence of an arc is detected by monitoring current and voltage in said system.

3. A method according to claim 2, wherein the occurrence of an arc is detected by monitoring a drop in voltage and an increase in current.

4. A method according to claim 1, wherein the time between propagation and reception is determined using correlation techniques.

5. Apparatus for determining the location of arcing in an electrical system comprising: an arc detector for detecting the occurrence of an arc; a generator for generating a signal on the system in response to an output from said detector; a signal detector for detecting a portion of said signal reflected from the location of the arcing; and a processor for determining the location of the arcing from the time between generation of said signal on the system and detection of said reflected portion.

6. Apparatus according to claim 5, wherein said arc detector is arranged to monitor current and voltage in said system.

7. Apparatus according to claim 6, wherein said arc detector is arranged to respond to a drop in voltage and an increase in current in said system.

8. Apparatus for determining the location of arcing in an electrical system comprising: arc detector means for detecting the occurrence of an arc; generator means for generating a signal on the system in response to an output from said detector means; signal detector means for detecting a portion of said signal reflected from the location of said arcing; and processor means for determining the location of said arcing from the time between generation of said signal on said system and detection of said reflected portion.

9. An electrical system comprising: a power generator; a load; a circuit connecting said load with said power generator; an arc detector for detecting the occurrence of an arc; a generator for generating a signal on the system in response to an output from said detector; a signal detector for detecting a portion of said signal reflected from the location of the arcing; and a processor for determining the location of the arcing from the time between generation of said signal on the system and detection of said reflected portion.

10. A system according to claim 9, wherein said arc detector is arranged to monitor current and voltage in said system.

11. A system according to claim 10, wherein said arc detector is arranged to respond to a drop in voltage and an increase in current in said system.
